(19) United States
(12) Patent Application Publication
(10) Pub. No.: US 2023/0058620 A1
(43) Pub. Date: Feb. 23, 2023

(54) MASK ASSEMBLY

(71) Applicant: Samsung Display Co., Ltd., Yongin-si (KR)

(72) Inventors: SEUNGJIN LEE, Suwon-si (KR); HONG-KYUN AHN, Hwaseong-si (KR); SANGHOON KIM, Hwaseong-si (KR); JONGSUNG PARK, Hwaseong-si (KR)

(21) Appl. No.: 17/824,991

(22) Filed: May 26, 2022

(30) Foreign Application Priority Data
Aug. 17, 2021 (KR) 10-2021-0108124

(51) Int. Cl. C23C 14/04

(52) U.S. Cl. CPC C23C 14/042

(57) ABSTRACT

A mask assembly includes: a frame; an open mask disposed on the frame, and defining a first deposition opening, a second deposition opening spaced apart from the first deposition opening in a first direction, and a first dummy opening located between the first deposition opening and the second deposition opening; and a shield member including a first shield part overlapping the first dummy opening in a plan view.

This application claims priority to Korean Patent Application No. 10-2021-0108124, filed on Aug. 17, 2021, and all the benefits accruing therefrom under 35 U.S.C. § 119, the content of which in its entirety is herein incorporated by reference.

### BACKGROUND

### 1. Technical Field

The disclosure relates generally to a mask assembly. More specifically, the disclosure relates to a mask assembly for thin film deposition.

### 2. THE BACKGROUND

As technology improves, display devices having smaller sizes, lighter weight, and superior performance have been produced. A cathode ray tube television, which is one of the display devices, has been widely used with many advantages in terms of performance and price. The cathode ray tube television has disadvantages in terms of miniaturization or portability. A display device that overcomes shortcomings of the cathode ray tube television in terms of miniaturization or portability and has advantages such as miniaturization, light weight, and low power consumption is attracting attention. For example, a plasma display device, a liquid crystal display device, an organic light emitting display device, and a quantum dot display device are attracting attention.

### SUMMARY

In order to manufacture the display device, components included in the display device may be formed in a plurality of cells formed on a mother substrate. An open mask may be used to form the components. The open mask may define a plurality of deposition openings corresponding to the cells. When the open mask is deformed during a process of manufacturing the display device, a defect may occur in the display device, including a case where the components are not formed in the cells.

Some embodiments provide a mask assembly with improved reliability.

A mask assembly includes: a frame; an open mask disposed on the frame, and defining a first deposition opening, a second deposition opening spaced apart from the first deposition opening in a first direction; and a first dummy opening located between the first deposition opening and the second deposition opening, and a shield member including a first shield part overlapping the first dummy opening in a plan view.

According to an embodiment, the shield member may be disposed between the frame and the open mask.

According to an embodiment, the first shield part may cover an entirety of the first dummy opening.

According to an embodiment, in the plan view, the shield member may be spaced apart from each of the first deposition opening and the second deposition opening.

According to an embodiment, the first shield part may extend in a second direction intersecting the first direction, and is fixed to the frame.

According to an embodiment, a distance between the first deposition opening and the first dummy opening may be smaller than a width of the first dummy opening in the first direction.

According to an embodiment, a width of the first shield part in the first direction may be greater than or equal to a width of the first dummy opening in the first direction.

According to an embodiment, a distance between the first deposition opening and the first dummy opening may be equal to a distance between the second deposition opening and the first dummy opening in the first direction.

According to an embodiment, the open mask may further define a third deposition opening spaced apart from the first deposition opening in a second direction intersecting the first direction, and a second dummy opening located between the first deposition opening and the third deposition opening.

According to an embodiment, the shield member may further include a second shield part protruding from the first shield part to overlap the second dummy opening in the plan view.

According to an embodiment, the second shield part may cover an entirety of the second dummy opening.

According to an embodiment, in the plan view, the shield member may be spaced apart from each of the first deposition opening and the third deposition opening.

According to an embodiment, the second shield part may extend in the second direction, and may be fixed to the frame.

According to an embodiment, a distance between the first deposition opening and the second dummy opening may be smaller than a width of the second dummy opening in the second direction.

According to an embodiment, a width of the second shield part in the second direction may be greater than or equal to a width of the second dummy opening in the second direction.

According to an embodiment, a distance between the first deposition opening and the second dummy opening may be equal to a distance between the third deposition opening and the second dummy opening in the second direction.

A mask assembly includes: a frame; an open mask disposed on the frame, and defining a first deposition opening, a second deposition opening spaced apart from the first deposition opening in a first direction, a third deposition opening spaced apart from the first deposition opening in a second direction intersecting the first direction, a first dummy opening located between the first deposition opening and the second deposition opening, and a second dummy opening located between the first deposition opening and the third deposition opening; and a shield member disposed between the frame and the open mask, and including a first shield part overlapping the first dummy opening, and a second shield part overlapping the second dummy opening in a plan view.

According to an embodiment, a distance between the first deposition opening and the first dummy opening may be smaller than a width of the first dummy opening in the first direction. A distance between the first deposition opening and the second dummy opening may be smaller than a width of the second dummy opening in the second direction.

According to an embodiment, a width of the first shield part in the first direction may be greater than or equal to a width of the first dummy opening in the first direction. A width of the second shield part in the second direction may be greater than or equal to a width of the second dummy opening in the second direction.

According to an embodiment, a distance between the first deposition opening and the first dummy opening may be equal to a distance between the second deposition opening and the first dummy opening in the first direction. A distance between the first deposition opening and the second dummy opening may be equal to a distance between the third deposition opening and the second dummy opening in the second direction.

The open mask may define a dummy opening located between adjacent deposition openings. A width of the open mask located between the adjacent deposition openings may be reduced. Since the width of the open mask is reduced, deformation of the open mask can be prevented or reduced during a thin film deposition process. Accordingly, reliability of the mask assembly including the open mask can be effectively improved.

It is to be understood that both the foregoing general description and the following detailed description are examples which are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventions.

FIG. 1 is an exploded perspective view showing a mask assembly according to an embodiment of the disclosure.

FIG. 2 is an enlarged plan view showing a region A of FIG. 1.

FIG. 3 is a plan view showing an open mask included in the mask assembly of FIG. 1.

FIG. 4 is a plan view showing a shield member included in the mask assembly of FIG. 1.

FIG. 5 is a sectional view taken along line I-I′ of FIG. 2.

FIG. 6 is a view showing a deposition process using the mask assembly of FIG. 1.

FIG. 7 is an exploded perspective view showing a mask assembly according to another embodiment of the disclosure.

FIG. 8 is an enlarged plan view showing a region B of FIG. 7.

FIG. 9 is a plan view showing an open mask included in the mask assembly of FIG. 7.

FIG. 10 is a plan view showing a shield member included in the mask assembly of FIG. 7.

### DETAILED DESCRIPTION

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Illustrative, non-limiting embodiments will be more clearly understood from the following detailed description in conjunction with the accompanying drawings.

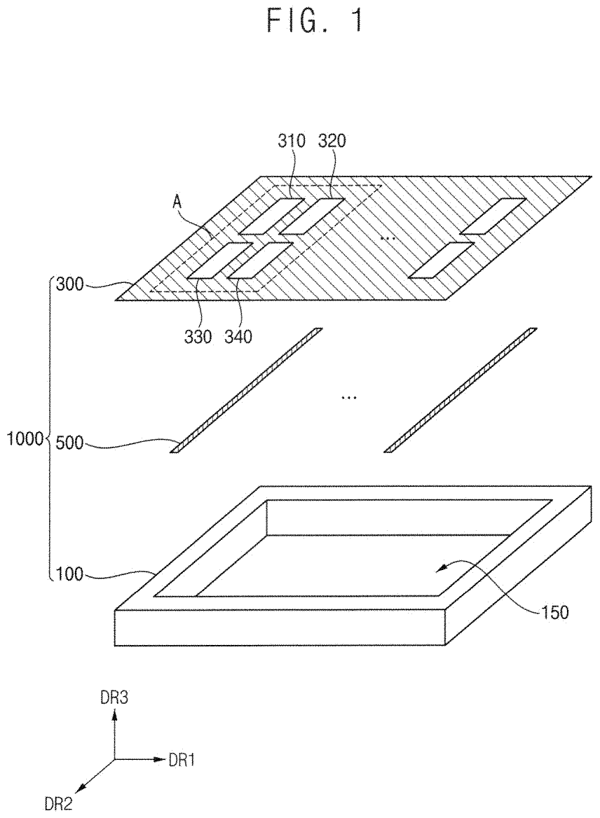

FIG. 1 is an exploded perspective view showing a mask assembly 1000 according to an embodiment of the disclosure.

Referring to FIG. 1, according to an embodiment of the disclosure, a mask assembly 1000 may include a frame 100, an open mask 300, and a shield member 500. For example, the mask assembly 1000 may be an apparatus for depositing a thin film in a plurality of cells formed on a mother substrate.

The frame 100 may be formed of or include a metal. The frame 100 may have a predetermined thickness in a thickness direction (i.e., third direction DR3). The frame 100 may define an opening 150.

The open mask 300 may be disposed on the frame 100. The open mask 300 may be formed of or include a metal. The open mask 300 may have a relatively thin thickness compared to the frame 100.

The open mask 300 may define a plurality of deposition openings. The deposition openings may include a first deposition opening 310, a second deposition opening 320, a third deposition opening 330, and a fourth deposition opening 340. Although the deposition openings have been shown as being arranged in two rows and n columns (where n is a natural number), the disclosure is not limited thereto. In another embodiment, for example, the open mask 300 may define a plurality of deposition openings arranged in m rows (where m is a natural number that is equal to or greater than 3) and n columns (where n is a natural number).

The deposition openings may be spaced apart from each other by a predetermined distance. The second deposition opening 320 may be spaced apart from the first deposition opening 310 in a first direction DR1. The third deposition opening 330 may be spaced apart from the first deposition opening 310 in a second direction DR2 intersecting the first direction DR1. The fourth deposition opening 340 may be spaced apart from the second deposition opening 320 in the second direction DR2, and may be spaced apart from the third deposition opening 330 in the first direction DR1. The second direction DR2 may be perpendicular to the first direction DR1. Areas of the deposition openings may be equal to each other.

The shield member 500 may be disposed on the frame 100. The shield member 500 may be disposed between the frame 100 and the open mask 300.

The shield member 500 may extend in the second direction DR2. The shield member 500 may be fixed to the frame 100. For example, the shield member 500 may be welded to the frame 100.

The shield member 500 may be formed of or include a metal. The shield member 500 may be formed of or include a metal that is the same as the metal constituting the open mask 300.

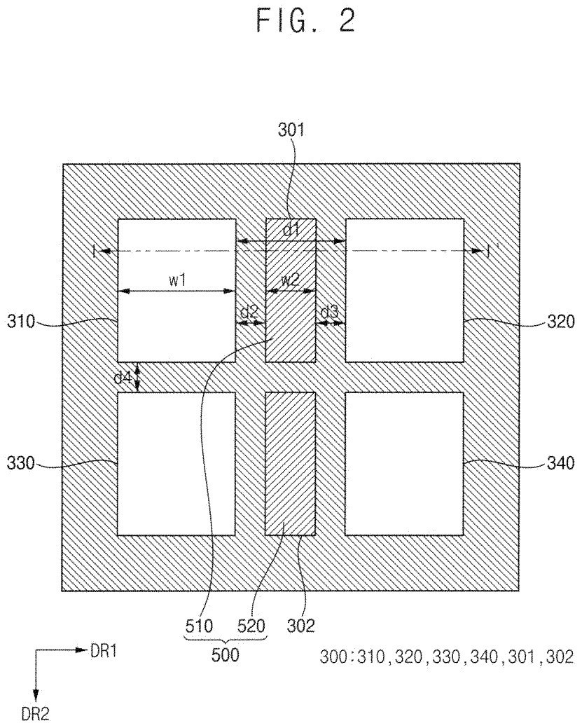

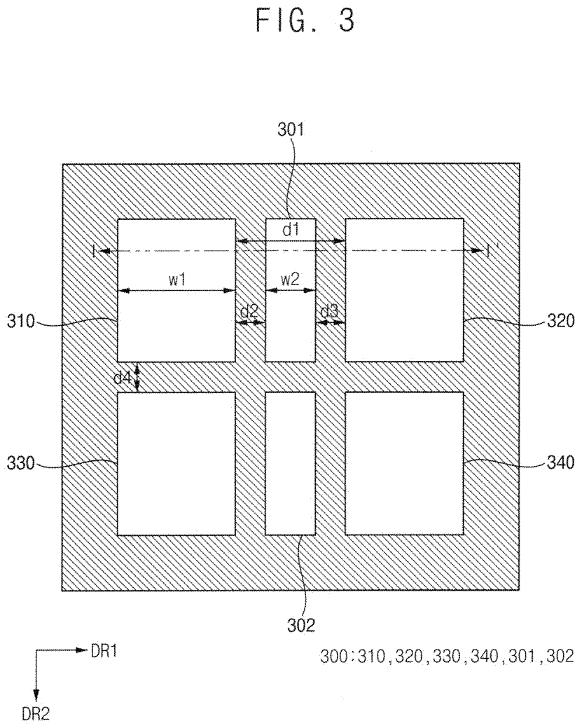

FIG. 2 is an enlarged plan view showing a region A of FIG. 1. For example, FIG. 2 may show the shield member 500 overlapping the opening 150 of the frame 100 and the open mask 300 disposed on the shield member 500 when viewed in a plan view. FIG. 3 is a plan view showing an open mask 300 included in the mask assembly 1000 of FIG. 1. Here, the plan view is defined as a view from a third direction DR3.

Referring to FIGS. 2 and 3, the open mask 300 may define a first deposition opening 310, a second deposition opening 320, a third deposition opening 330, a fourth deposition opening 340, a (1-1) dummy opening 301, and a (1-2) dummy opening 302. For example, the first deposition opening 310, the second deposition opening 320, the third deposition opening 330, and the fourth deposition opening 340 may be openings through which a deposition material passes during a thin film deposition process. The (1-1) dummy opening 301 and the (1-2) dummy opening 302 may be openings through which the deposition material does not pass during the thin film deposition process. During the thin film deposition process, a thin film may be formed in regions of the mother substrate disposed on the mask assembly 1000, which correspond to the first deposition opening 310, the second deposition opening 320, the third deposition opening 330, and the fourth deposition opening 340.

The second deposition opening 320 may be spaced apart from the first deposition opening 310 in the first direction DR1. The third deposition opening 330 may be spaced apart from the first deposition opening 310 in the second direction DR2. The fourth deposition opening 340 may be spaced apart from the second deposition opening 320 in the second direction DR2, and may be spaced apart from the third deposition opening 330 in the first direction DR1. The (1-1) dummy opening 301 may be located between the first deposition opening 310 and the second deposition opening 320. The (1-2) dummy opening 302 may be located between the third deposition opening 330 and the fourth deposition opening 340.

Each of the first deposition opening 310, the second deposition opening 320, the third deposition opening 330, the fourth deposition opening 340, the (1-1) dummy opening 301, and the (1-2) dummy opening 302 may have a width in the first direction DR1, and a length in the second direction DR2.

The width w1 of the first deposition opening 310, the width of the second deposition opening 320, the width of the third deposition opening 330, and the width of the fourth deposition opening 340 may be equal to each other. The length of the first deposition opening 310, the length of the second deposition opening 320, the length of the third deposition opening 330, and the length of the fourth deposition opening 340 may be equal to each other. An area of the first deposition opening 310, an area of the second deposition opening 320, an area of the third deposition opening 330, and an area of the fourth deposition opening 340 may be equal to each other.

The width w2 of the (1-1) dummy opening 301 and the width w2 of the (1-2) dummy opening 302 may be equal to each other. The length of the (1-1) dummy opening 301 and the length of the (1-2) dummy opening 302 in the second direction DR2 may be equal to each other. An area of the (1-1) dummy opening 301 and an area of the (1-2) dummy opening 302 may be equal to each other.

A distance d1 between the first deposition opening 310 and the second deposition opening 320 in the first direction DR1 may be smaller than the width w1 of the first deposition opening 310. Area efficiency of the mother substrate may be increased by reducing a distance between the cells formed on the mother substrate.

A distance d4 between the first deposition opening 310 and the third deposition opening 330 in the second direction DR2 may be smaller than the distance d1 between the first deposition opening 310 and the second deposition opening 320 in the first direction DR1.

A distance d2 between the first deposition opening 310 and the (1-1) dummy opening 301 in the first direction DR1 may be equal to a distance d3 between the second deposition opening 320 and the (1-1) dummy opening 301 in the first direction DR1. The (1-1) dummy opening 301 may be located in the middle between the first deposition opening 310 and the second deposition opening 320. The (1-2) dummy opening 302 may be located in the middle between the third deposition opening 330 and the fourth deposition opening 340.

According to an embodiment, the distance d2 between the first deposition opening 310 and the (1-1) dummy opening 301 may be smaller than the width w2 of the (1-1) dummy opening 301. According to another embodiment, the distance d2 between the first deposition opening 310 and the (1-1) dummy opening 301 may be greater than or equal to the width w2 of the (1-1) dummy opening 301. However, the distance d2 between the first deposition opening 310 and the (1-1) dummy opening 301 is preferably smaller than the width w2 of the (1-1) dummy opening 301 in the first direction DR1. The reason why it is preferable to set the distance d2 between the first deposition opening 310 and the (1-1) dummy opening 301 to be smaller will be described below.

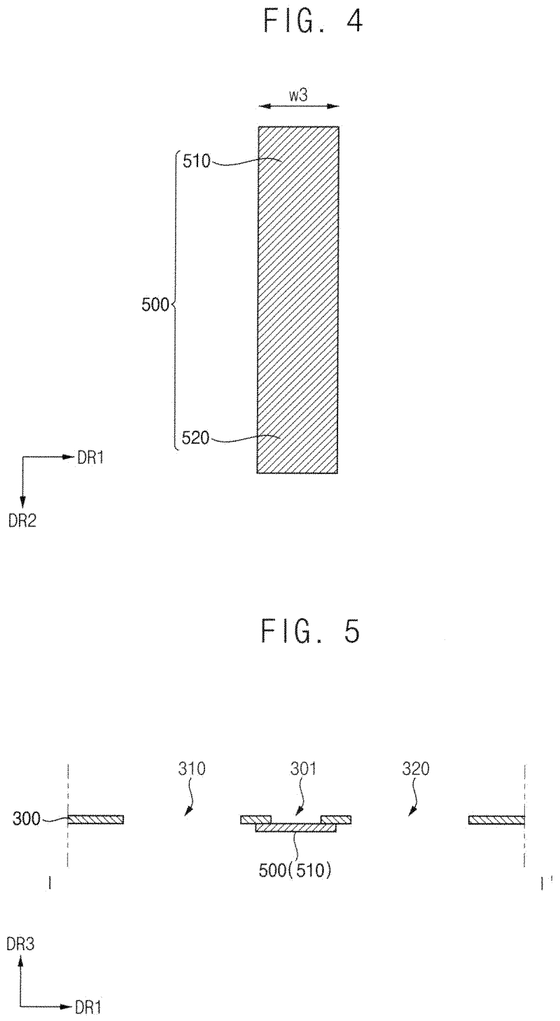

FIG. 4 is a plan view showing a shield member 500 included in the mask assembly 1000 of FIG. 1. FIG. 5 is a sectional view taken along line I-I′ of FIG. 2.

Referring to FIGS. 2, 4, and 5, the shield member 500 may be disposed under the open mask 300.

The shield member 500 may include a first portion 510 and a second portion 520. The first portion 510 and the second portion 520 may be connected to each other in the second direction DR2. The shield member 500 may extend in the second direction DR2.

The first portion 510 may overlap the (1-1) dummy opening 301. The second portion 520 may overlap the (1-2) dummy opening 302. The shield member 500 may overlap the (1-1) dummy opening 301 and the (1-2) dummy opening 302 in a plan view.

The shield member 500 may have a width w3 in the first direction DR1, and a length in the second direction DR2. The length of the shield member 500 may be sufficient to allow the shield member 500 to overlap the frame 100. At least a portion of the shield member 500 may be welded and fixed to the frame 100.

A width w3 of the shield member 500 may be greater than or equal to the width w2 of the (1-1) dummy opening 301. Preferably, the width w3 of the shield member 500 may be greater than the width w2 of the (1-1) dummy opening 301. For example, the width w3 of the shield member 500 may be equal to a sum of the width w2 of the (1-1) dummy opening 301, a half of the distance d2 between the first deposition opening 310 and the (1-1) dummy opening 301, and a half the distance d3 between the second deposition opening 320 and the (1-1) dummy opening 301.

The shield member 500 may cover the entirety of the (1-1) dummy opening 301 and the (1-2) dummy opening 302. The first portion 510 may cover the entirety of the (1-1) dummy opening 301, and the second portion 520 may cover the entirety of the (1-2) dummy opening 302. Therefore, the deposition material may not pass through the (1-1) dummy opening 301 and the (1-2) dummy opening 302 during the thin film deposition process.

The width w3 of the shield member 500 may be smaller than the distance d1 between the first deposition opening 310 and the second deposition opening 320. The shield member 500 may be spaced apart from each of the first deposition opening 310 and the second deposition opening 320 on a plane defined by the first direction DR1 and the second direction DR2. The shield member 500 may not overlap the first deposition opening 310, the second deposition opening 320, the third deposition opening 330, and the fourth deposition opening 340. The shield member 500 may not obstruct the deposition material from passing through the first deposition opening 310, the second deposition opening 320, the third deposition opening 330, and the fourth deposition opening 340 during the thin film deposition process. The shield member 500 may serve to prevent the deposition material from passing through the (1-1) dummy opening 301 and the (1-2) dummy opening 302.

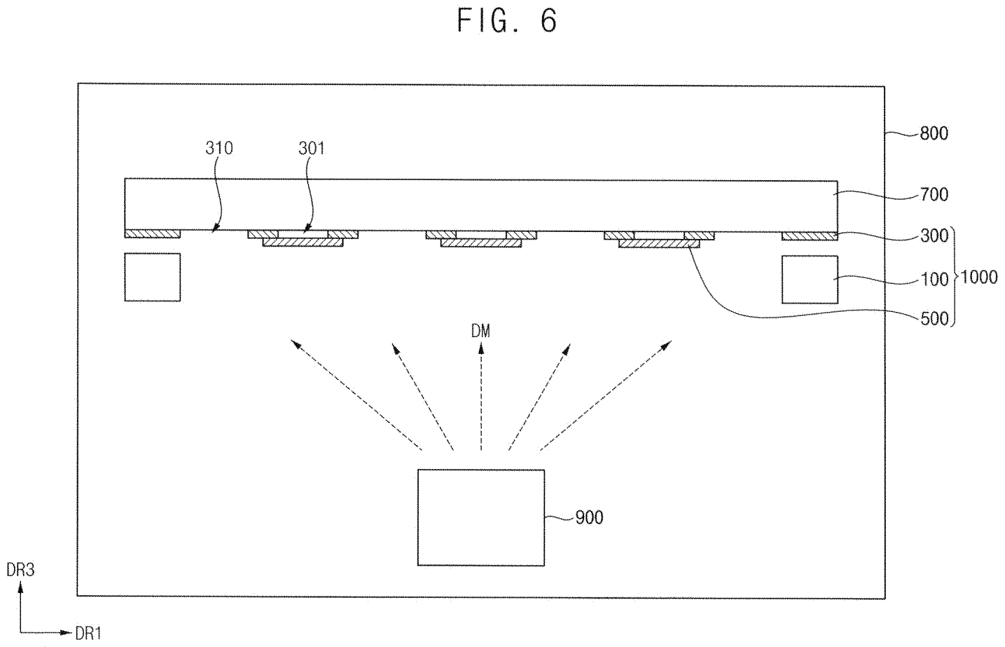

FIG. 6 is a view showing a deposition process using the mask assembly 1000 of FIG. 1.

Referring to FIG. 6, the deposition process may be performed in a deposition chamber 800.

The mask assembly 1000, a mother substrate 700, and a deposition source 900 may be disposed inside the deposition chamber 800.

The deposition source 900 may spray a deposition material DM substantially in a third direction DR3. The third direction DR3 may be perpendicular to the plane defined by the first direction DR1 and the second direction DR2. The third direction DR3 may be a direction opposite to a direction of gravity.

The deposition source 900 may spray the deposition material DM toward the mother substrate 700. The sprayed deposition material DM may be deposited onto the mother substrate 700. The deposition material DM may form a thin film on the mother substrate 700.

The mother substrate 700 may be spaced apart from the deposition source 900 in the third direction DR3. The mother substrate 700 may include glass, plastic, or the like. The mother substrate 700 may be a semi-finished display panel or a finished display panel.

The mask assembly 1000 may be adjacent to the mother substrate 700. The mask assembly 1000 may be disposed under the mother substrate 700.

The mask assembly 1000 may make close contact with the mother substrate 700.

Although not shown, the mask assembly 1000 may make close contact with the mother substrate 700 by a magnetic force formed between the mask assembly 1000 and a magnet disposed on the mother substrate 700.

The shield member 500 may be disposed between the frame 100 and the open mask 300. The deposition material DM may pass through the mask assembly 1000. The deposition material DM may pass through the opening 150 of the frame 100. The deposition material DM may pass through a plurality of deposition openings of the open mask 300. The deposition material DM may not pass through a plurality of dummy openings covered by the shield member 500. A thin film may be formed at preset positions of the mother substrate 700 through the open mask 300 defining the deposition openings at the preset positions.

According to a comparative example, a mask assembly may not include a shield member, and an open mask may not define a plurality of dummy openings. In the comparative example, during the thin film deposition process, a portion of the open mask may be deformed. For example, a lattice part of the open mask, which is located between adjacent deposition openings, may be bent. The lattice part of the open mask in the comparative example may be bent such that a central portion of the lattice part in a width direction (e.g., the first direction DR1 of FIG. 6) faces downward, and opposite ends of the lattice part face upward. The mother substrate may be damaged by the opposite ends of the lattice part of the open mask. For example, the mother substrate may be stabbed by the opposite ends of the lattice part of the open mask that is bent in a U-shape such that the opposite ends of the lattice part face upward. Since the mother substrate is damaged, particles may be generated. Reliability of the thin film deposition process in the comparative example may be reduced. As a width of the lattice part of the open mask becomes larger, the lattice part of the open mask may be bent more. As the lattice part of the open mask in the comparative example is bent more, the substrate may be damaged more, and possibility of generating the particles may be increased.

In contrast, referring to FIG. 2, according to an embodiment of the disclosure, the mask assembly 1000 may include the open mask 300 defining a plurality of dummy openings 301 and 302 therein. Each of the widths d2 and d3 of lattice parts of the open mask 300 located between adjacent deposition openings 310 and 320 may be smaller than a width d1 of the lattice part of the open mask according to the comparative example. According to the mask assembly 1000 of an embodiment of the disclosure, deformation of the open mask 300 (e.g., bending of each of the lattice parts of the open mask 300) may be effectively prevented or reduced during the thin film deposition process. Damage to the mother substrate 700 may be prevented or reduced, and generation of particles may be prevented or reduced. The reliability of the thin film deposition process may be effectively improved.

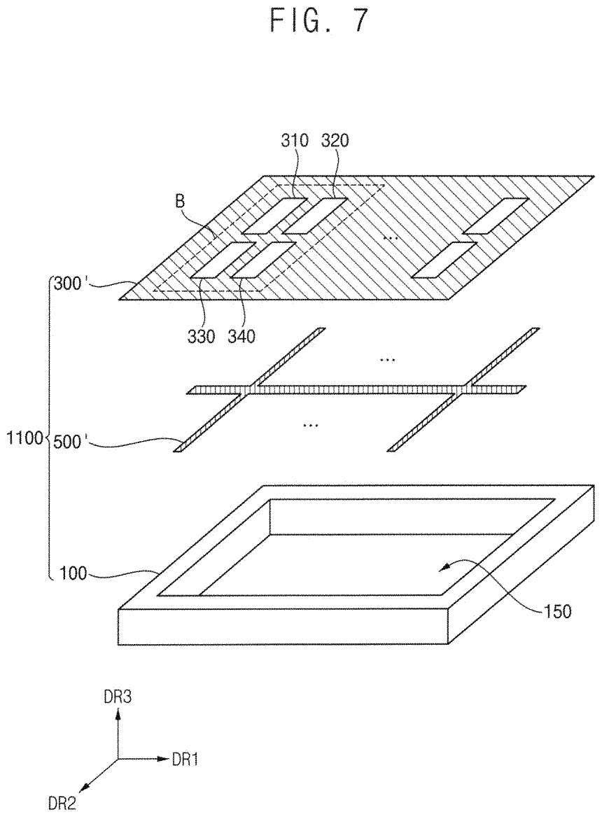

FIG. 7 is an exploded perspective view showing a mask assembly 1100 according to another embodiment of the disclosure. A mask assembly 1100 according to another embodiment of the disclosure may be substantially the same as the mask assembly 1000 described with reference to FIG. 1 except for an open mask 300′ and a shield member 500′. Therefore, redundant descriptions thereof will be omitted.

Referring to FIG. 7, according to another embodiment of the disclosure, the mask assembly 1100 may include a frame 100, an open mask 300′, and a shield member 500′. The shield member 500′ may be configured as one body (i.e., monolithic).

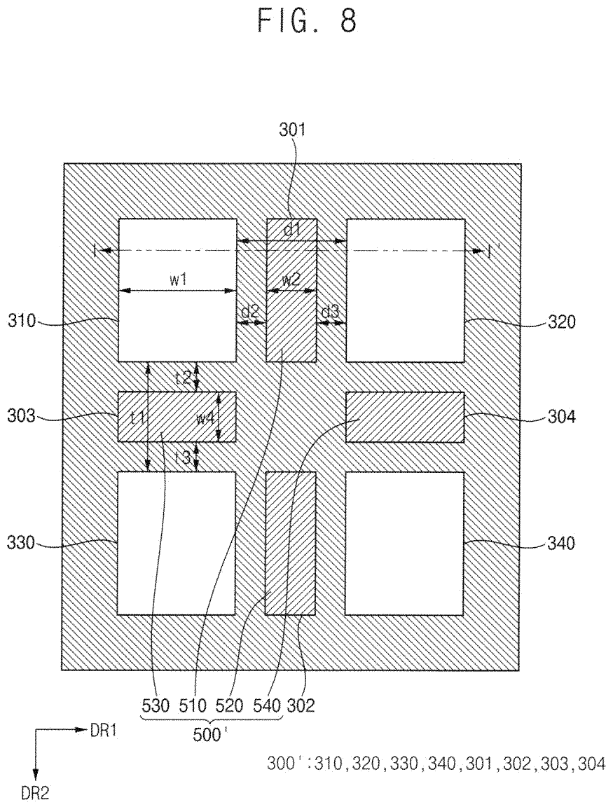

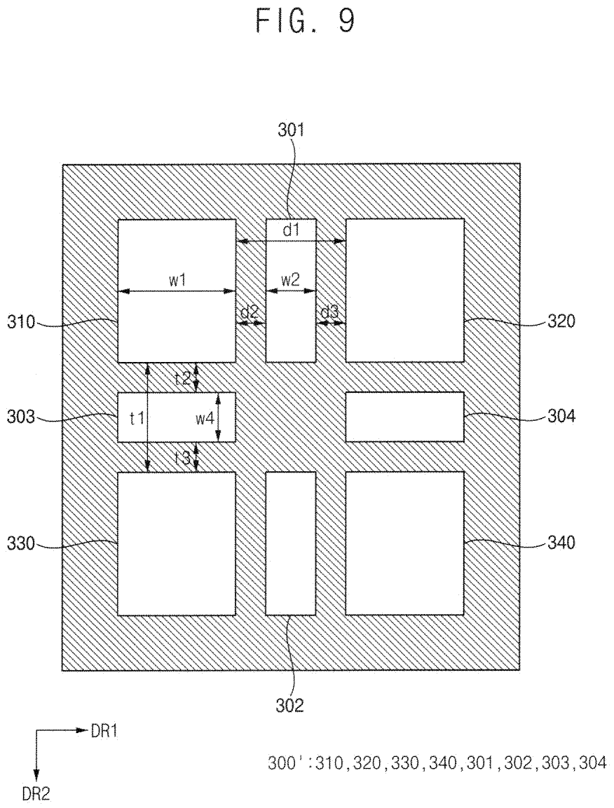

FIG. 8 is an enlarged plan view showing a region B of FIG. 7. FIG. 9 is a plan view showing an open mask 300′ included in the mask assembly 1100 of FIG. 7.

Referring to FIGS. 8 and 9, the open mask 300′ may define a first deposition opening 310, a second deposition opening 320, a third deposition opening 330, a fourth deposition opening 340, a (1-1) dummy opening 301, a (1-2) dummy opening 302, a (2-1) dummy opening 303, and a (2-2) dummy opening 304. For example, since a distance t1 between the first deposition opening 310 and the third deposition opening 330 in the second direction DR2 is sufficiently large, the open mask 300′ may further define the (2-1) dummy opening 303 and the (2-2) dummy opening 304.

The (2-1) dummy opening 303 may be located between the first deposition opening 310 and the third deposition opening 330. The (2-2) dummy opening 304 may be located between the second deposition opening 320 and the fourth deposition opening 340.

Each of the (2-1) dummy opening 303 and the (2-2) dummy opening 304 may have a width in the second direction DR2, and a length in the first direction DR1.

The width w4 of the (2-1) dummy opening 303 and the width of the (2-2) dummy opening 304 may be equal to each other. The length of the (2-1) dummy opening 303 and the length of the (2-2) dummy opening 304 may be equal to each other. An area of the (2-1) dummy opening 303 and an area of the (2-2) dummy opening 304 may be equal to each other.

A distance t2 between the first deposition opening 310 and the (2-1) dummy opening 303 in the second direction DR2 may be equal to a distance t3 between the third deposition opening 330 and the (2-1) dummy opening 303 in the second direction DR2. The (2-1) dummy opening 303 may be located in the middle between the first deposition opening 310 and the third deposition opening 330. The (2-2) dummy opening 304 may be located in the middle between the second deposition opening 320 and the fourth deposition opening 340.

According to an embodiment, the distance t2 between the first deposition opening 310 and the (2-1) dummy opening 303 may be smaller than the width w4 of the (2-1) dummy opening 303. According to another embodiment, the distance t2 between the first deposition opening 310 and the (2-1) dummy opening 303 may be greater than or equal to the width w4 of the (2-1) dummy opening 303. However, the distance t2 between the first deposition opening 310 and the (2-1) dummy opening 303 is preferably smaller than the width w4 of the (2-1) dummy opening 303. As the width w4 of the (2-1) dummy opening 303 becomes larger, the distance t2 between the first deposition opening 310 and the (2-1) dummy opening 303 may become smaller. Deformation of the open mask 300′ located between the first deposition opening 310 and the third deposition opening 330 (e.g., a lattice part of the open mask 300′) may be effectively prevented or reduced.

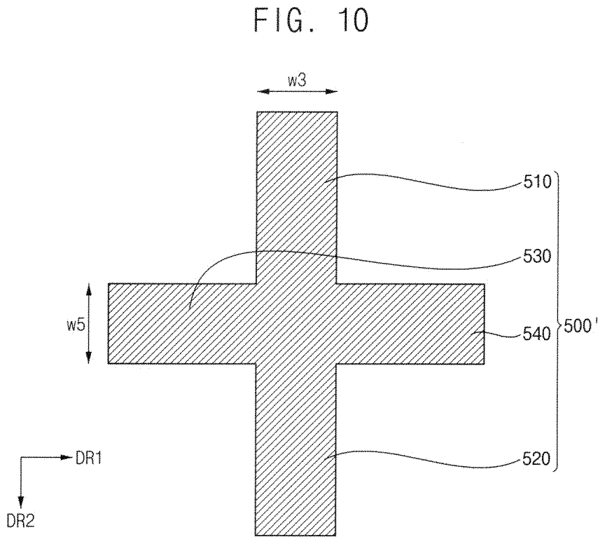

FIG. 10 is a plan view showing a shield member 500′ included in the mask assembly 1100 of FIG. 7.

Referring to FIGS. 8 and 10, the shield member 500′ may include a first shield part 510 and 520 and a second shield part 530 and 540. The first shield part 510 and 520 may include a first portion 510 and a second portion 520. The second shield part 530 and 540 may include a third portion 530 and a fourth portion 540. The second shield part 530 and 540 may protrude from the first shield part 510 and 520. For example, the third portion 530 may protrude from the first portion 510 or the second portion 520 in the first direction DR1. The third portion 530 and the fourth portion 540 may be connected to each other in the first direction DR1. The second shield part 530 and 540 may extend in the first direction DR1. The shield member 500′ may be configured as one body (i.e., monolithic).

The third portion 530 of the second shield part 530 and 540 may overlap the (2-1) dummy opening 303. The fourth portion 540 of the second shield part 530 and 540 may overlap the (2-2) dummy opening 304. The second shield part 530 and 540 may overlap the (2-1) dummy opening 303 and the (2-2) dummy opening 304 in a plan view. The shield member 500′ may overlap the (1-1) dummy opening 301, the (1-2) dummy opening 302, the (2-1) dummy opening 303, and the (2-2) dummy opening 304.

The second shield part 530 and 540 may have a width w5 in the second direction DR2, and a length in the first direction DR1. The length of the second shield part 530 and 540 may be sufficient to allow the second shield part 530 and 540 to overlap the frame 100. At least a portion of the second shield part 530 and 540 may be fixed to the frame 100. For example, at least a portion of the second shield part 530 and 540 may be welded to the frame 100.

The width w5 of the second shield part 530 and 540 may be greater than or equal to the width w4 of the (2-1) dummy opening 303 in the second direction DR2. Preferably, the width w5 of the second shield part 530 and 540 may be greater than the width w4 of the (2-1) dummy opening 303. For example, the width w5 of the second shield part 530 and 540 may be equal to a sum of the width w4 of the (2-1) dummy opening 303, a half of the distance t2 between the first deposition opening 310 and the (2-1) dummy opening 303, and a half the distance t3 between the third deposition opening 330 and the (2-1) dummy opening 303. By these length relations mentioned above, even when the second shield part 530 and 540 is deformed, the second shield part 530 and 540 may serve to prevent the deposition material DM from passing through the (2-1) dummy opening 303 and the (2-2) dummy opening 304.

The second shield part 530 and 540 may cover the entirety of the (2-1) dummy opening 303 and the (2-2) dummy opening 304. The third portion 530 may cover the entirety of the (2-1) dummy opening 303, and the fourth portion 540 may cover the entirety of the (2-2) dummy opening 304 in a plan view. The deposition material DM may not pass through the (2-1) dummy opening 303 and the (2-2) dummy opening 304 during the thin film deposition process.

The width w5 of the second shield part 530 and 540 may be smaller than the distance t1 between the first deposition opening 310 and the third deposition opening 330. The second shield part 530 and 540 may be spaced apart from each of the first and third deposition openings 310 and 330 on the plane defined by the first direction DR1 and the second direction DR2. The shield member 500′ may not overlap the first deposition opening 310, the second deposition opening 320, the third deposition opening 330, and the fourth deposition opening 340 in a plan view. The shield member 500′ may not obstruct the deposition material DM from passing through the first deposition opening 310, the second deposition opening 320, the third deposition opening 330, and the fourth deposition opening 340 during the thin film deposition process. The shield member 500′ may serve to prevent the deposition material DM from passing through the (1-1) dummy opening 301, the (1-2) dummy opening 302, the (2-1) dummy opening 303, and the (2-2) dummy opening 304.

Although certain embodiments and implementations have been described herein, other embodiments and modifications will be apparent from this description. Accordingly, the inventions are not limited to such embodiments, but rather to the broader scope of the appended claims and various obvious modifications and equivalent arrangements as would be apparent to a person of ordinary skill in the art.

What is claimed is:

1. A mask assembly comprising:
a frame;
an open mask disposed on the frame, and defining a first deposition opening, a second deposition opening spaced apart from the first deposition opening in a first direction, and a first dummy opening located between the first deposition opening and the second deposition opening; and
a shield member including a first shield part overlapping the first dummy opening in a plan view.

2. The mask assembly of claim 1, wherein the shield member is disposed between the frame and the open mask.

3. The mask assembly of claim 1, wherein the first shield part covers an entirety of the first dummy opening.

4. The mask assembly of claim 1, wherein, in the plan view, the shield member is spaced apart from each of the first deposition opening and the second deposition opening.

5. The mask assembly of claim 1, wherein the first shield part extends in a second direction intersecting the first direction, and is fixed to the frame.

6. The mask assembly of claim 1, wherein a distance between the first deposition opening and the first dummy opening is smaller than a width of the first dummy opening in the first direction.

7. The mask assembly of claim 1, wherein a width of the first shield part in the first direction is greater than or equal to a width of the first dummy opening in the first direction.

8. The mask assembly of claim 1, wherein a distance between the first deposition opening and the first dummy opening is equal to a distance between the second deposition opening and the first dummy opening in the first direction.

9. The mask assembly of claim 1, wherein the open mask further defines a third deposition opening spaced apart from the first deposition opening in a second direction intersecting the first direction, and a second dummy opening located between the first deposition opening and the third deposition opening.

10. The mask assembly of claim 9, wherein the shield member further includes a second shield part protruding from the first shield part to overlap the second dummy opening in the plan view.

11. The mask assembly of claim 10, wherein the second shield part covers an entirety of the second dummy opening.

12. The mask assembly of claim 10, wherein, in the plan view, the shield member is spaced apart from each of the first deposition opening and the third deposition opening.

13. The mask assembly of claim 10, wherein the second shield part extends in the second direction, and is fixed to the frame.

14. The mask assembly of claim 10, wherein a distance between the first deposition opening and the second dummy opening is smaller than a width of the second dummy opening in the second direction.

15. The mask assembly of claim 10, wherein a width of the second shield part in the second direction is greater than or equal to a width of the second dummy opening in the second direction.

16. The mask assembly of claim 10, wherein a distance between the first deposition opening and the second dummy opening is equal to a distance between the third deposition opening and the second dummy opening in the second direction.

17. A mask assembly comprising:
a frame;
an open mask disposed on the frame, and defining a first deposition opening, a second deposition opening spaced apart from the first deposition opening in a first direction, a third deposition opening spaced apart from the first deposition opening in a second direction intersecting the first direction, a first dummy opening located between the first deposition opening and the second deposition opening, and a second dummy opening located between the first deposition opening and the third deposition opening; and
a shield member disposed between the frame and the open mask, and including a first shield part overlapping the first dummy opening, and a second shield part overlapping the second dummy opening in a plan view.

18. The mask assembly of claim 17, wherein a distance between the first deposition opening and the first dummy opening is smaller than a width of the first dummy opening in the first direction, and
a distance between the first deposition opening and the second dummy opening is smaller than a width of the second dummy opening in the second direction.

19. The mask assembly of claim 17, wherein a width of the first shield part in the first direction is greater than or equal to a width of the first dummy opening in the first direction, and
a width of the second shield part in the second direction is greater than or equal to a width of the second dummy opening in the second direction.

20. The mask assembly of claim 17, wherein a distance between the first deposition opening and the first dummy opening is equal to a distance between the second deposition opening and the first dummy opening in the first direction, and
a distance between the first deposition opening and the second dummy opening is equal to a distance between the third deposition opening and the second dummy opening in the second direction.
